(19) United States
(12) Patent Application Publication
(10) Pub. No.: US 2012/0199171 A1
(43) Pub. Date: Aug. 9, 2012

(54) THERMOELECTRIC GENERATION UTILIZING NANOFLUID

(75) Inventor: Phillip C. Watts, Longmont, CO (US)

(73) Assignee: Watts Thermoelectric, LLC, Aspen, CO (US)

(21) Appl. No.: 13/035,479

(22) Filed: Feb. 25, 2011

Related U.S. Application Data
(60) Provisional application No. 61/440,273, filed on Feb. 7, 2011.

(51) Int. Cl. H01L 35/30; H01J 27/02

(52) U.S. Cl. 136/205; 136/212; 315/111.81

(57) ABSTRACT

According to one aspect, a system generates electricity from a temperature differential using a thermoelectric module. At least one side of the temperature differential is supplied by a thermal element having a fluid flowing through it. The fluid contains suspended nanoparticles to enhance the transfer of heat between the fluid containing the nanoparticles and the thermal element, as compared with a similar fluid not containing the nanoparticles. The nanoparticles may include metal ions, for example silver ions, copper ions, or both. The system may further include an ion generator for generating the ions within the fluid.

This application claims the benefit of U.S. Provisional Patent Application No. 61/440,273, filed Feb. 7, 2011 and titled “Thermoelectric Generation Utilizing Nanofluid”, the entire disclosure of which is hereby incorporated by reference herein.

### BACKGROUND OF THE INVENTION

A thermoelectric module is a device that exploits the thermoelectric effect exhibited by many materials. FIG. 1 shows a schematic diagram of the operation of a thermoelectric module 100. A thermoelectric module such as module 100 has the property that when current is passed through the module, for example at terminals 101, one side 102 of the module is cooled and the other side 103 is heated. Thermoelectric modules are used in this way in certain consumer devices such as water coolers and the like.

The thermoelectric effect is reversible, such that when the two sides of a thermoelectric module are held at different temperatures, the module can generate electric power. For example, in FIG. 1, rather than driving a current through terminals 101 to heat and cool module sides 102 and 103, the module sides 102 and 103 may be held in a temperature differential, and a voltage will be produced across terminals 101. When used to generate power, a thermoelectric module may be called a thermoelectric generator (TEG). The voltage produced and the amount of power available from the module depend on the temperature differential between the two sides 102 and 103, the materials used to construct the module, the absolute temperature at which the module is operated, the size of the module, and other factors.

### BRIEF SUMMARY OF THE INVENTION

According to one aspect, a system for generating electricity from a temperature differential includes at least one thermoelectric module having a hot side and a cold side, and a thermal element in contact with one side of the thermoelectric module, to supply heat to or to receive heat from the thermoelectric module. The system also includes a fluid flowing through the thermal element, to supply heat to or to receive heat from the thermal element, and a plurality of nanoparticles suspended in the fluid. The suspended nanoparticles enhance the transfer of heat between the fluid containing the nanoparticles and the thermal element, as compared with a similar fluid not containing the nanoparticles. In some embodiments, the thermal element is a hot thermal element in contact with the hot side of the thermoelectric module to supply heat to the thermoelectric module, the fluid is a hot fluid flowing through the hot thermal element to supply heat to the hot thermal element, the nanoparticles are a first plurality of nanoparticles suspended in the hot fluid, and the system further includes a cold thermal element in contact with the cold side of the thermoelectric module, to receive heat from the thermoelectric module, and a cold fluid flowing through the cold thermal element to receive heat from the cold thermal element. A second plurality of nanoparticles is suspended in the cold fluid, and the suspended nanoparticles enhance the transfer of heat between the cold fluid containing the nanoparticles and the thermal element, as compared with a similar fluid not containing the nanoparticles. In some embodiments, the fluid is water, and the suspended nanoparticles comprise copper ions, silver ions, or both copper and silver ions. The ions may be less than 2 nanometers in diameter.

The ions may be non-colloidal. In some embodiments, the fluid contains copper ions in a concentration of between 250 and 450 micrograms per liter. In some embodiments, the fluid contains silver ions in a concentration of between 150 and 350 micrograms per liter. The fluid may be contained within a closed loop. In some embodiments, the system further includes a heat exchanger that transfers heat from an external source to the fluid to heat the fluid, or transfers heat from the fluid to an external sink to cool the fluid. The system may further include an ion generator that generates the nanoparticles. In some embodiments, the ion generator includes a spaced apart pair of electrodes in contact with the fluid, and a drive circuit that applies an alternating voltage between the electrodes. The alternating voltage may be a chopped alternating voltage. Each electrode may be made of sterling silver. The alternating voltage may have a peak-to-peak amplitude of between 4 and 6 volts. The alternating voltage may have a frequency of between 6 and 8 Hz. The alternating voltage may have a frequency greater than 20 kHz. In some embodiments, the system further includes a plurality of thermoelectric modules having hot and cold sides and a plurality of thermal elements in contact the thermoelectric modules, to supply heat to or to receive heat from the thermoelectric module, and the fluid flows through the plurality of thermal elements, to supply heat to or to receive heat from at least some of the thermal elements.

According to another aspect, an ion generator for generating ions in a fluid includes a spaced apart pair of electrodes in contact with the fluid, and a drive circuit that applies an alternating voltage between the electrodes, the alternating voltage having a frequency of at least 6 Hz. In some embodiments, the alternating voltage is a chopped alternating voltage. In some embodiments, each electrode comprises copper, silver, or both. Both electrodes may be made of sterling silver. In some embodiments, the alternating voltage alternates at a frequency between 6 Hz and 8 Hz. In some embodiments, the alternating voltage alternates at a frequency greater than 20 kHz.

According to another aspect, a method of generating electricity from a temperature differential includes placing a thermal element in contact with a side of a thermoelectric module, passing a fluid through the thermal element to supply heat to or to receive heat from the thermoelectric module, and suspending nanoparticles within the fluid. The nanoparticles enhance the transfer of heat between the fluid containing the nanoparticles and the thermal element as compared with a similar fluid not containing the nanoparticles. In some embodiments, the thermal element is a hot thermal element in contact with a hot side of the thermoelectric module and the fluid is a hot fluid that supplies heat to the thermoelectric module, and the method further includes placing a cold thermal element in contact with a cold side of the thermoelectric module, passing a cold fluid through the cold thermal element to receive heat from the thermoelectric module, and suspending nanoparticles within the cold fluid, the nanoparticles enhancing the transfer of heat between the cold fluid containing the nanoparticles and the cold thermal element as compared with a similar fluid not containing the nanoparticles. In some embodiments, suspending nanoparticles within the fluid comprises providing a pair of spaced apart electrodes in contact with the fluid, and impressing an alternating voltage between the electrodes to generate nanoparticles via electrolysis. In some embodiments, providing a pair of spaced apart electrodes in contact with the fluid comprises providing at least one electrode that comprises silver, copper, or both silver and copper. In some embodiments, providing a pair of spaced apart electrodes in contact with the fluid comprises providing a pair of sterling silver electrodes. In some embodiments, impressing the alternating voltage between the electrodes comprises impressing a chopped alternating voltage between the electrodes. The method may further include impressing the alternating voltage between the electrodes continuously during the generation of electricity by the thermoelectric module. In some embodiments, impressing the alternating voltage between the electrodes comprises impressing an alternating voltage having a frequency between 6 and 8 Hz between the electrodes.

### BRIEF DESCRIPTION OF THE DRAWINGS

FIG. 1 shows a thermoelectric module usable in embodiments.

FIG. 2 illustrates a system in accordance with embodiments.

FIG. 3 shows an arrangement of components for exposing a single thermoelectric module to a temperature differential, in accordance with embodiments.

FIG. 4 illustrates one way of constructing a thermoelectric generator having a plurality of thermoelectric modules, in accordance with embodiments.

FIG. 5 illustrates a system for utilizing one or more nanofluids in thermoelectric power generation, in accordance with embodiments.

FIG. 6 illustrates the operation of an ion generator, in accordance with embodiments.

FIG. 7 illustrates a system for generating electricity from waste heat, in accordance with embodiments.

### DETAILED DESCRIPTION OF THE INVENTION

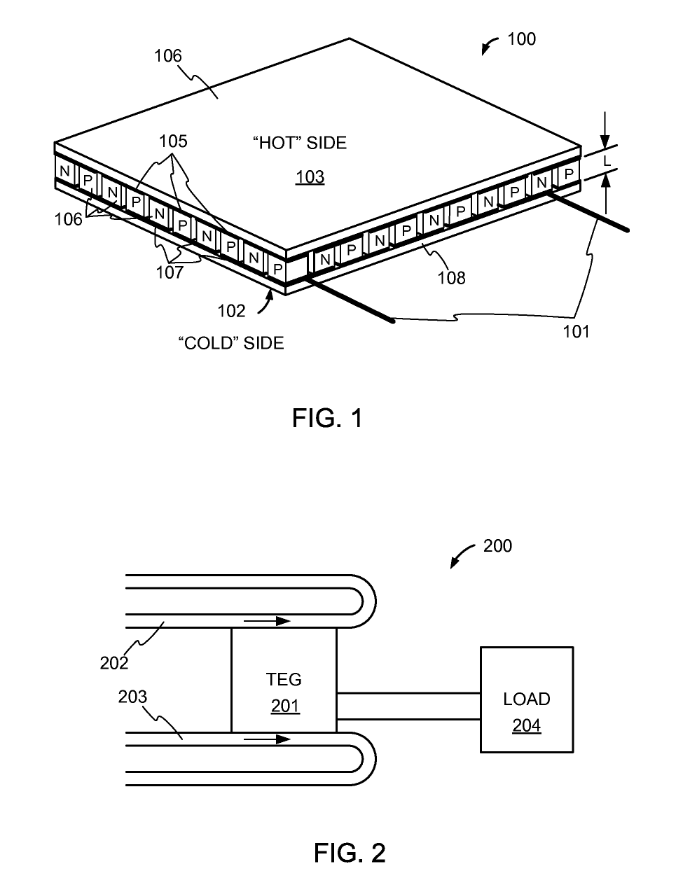

Thermoelectric module 100 is an example of a thermoelectric device usable in embodiments. Module 100 is made up of a number of thermoelectric elements 104, each of which is a length of conductive or semiconductive material with favorable thermoelectric properties. For example, the elements may be pieces of n-type and p-type semiconductor material, labeled “N” and “P” in FIG. 1. The thermoelectric elements 104 are arranged in thermoelectric couples, each thermoelectric couple including one “N” element and one “P” element. The ends of the elements in each thermoelectric couple are electrically connected at hot side 103 of module 100 by one of conductors 105, and are further thermally connected to a heat source through an optional header 106. The various thermoelectric couples are connected in series at cold side 102 of module 100, by conductors 107, and are also thermally connected to a “cold” source or header 108 at the cold side 103 of module 100. Each thermoelectric couple generates a relatively small voltage, and the voltage appearing at leads 101 is the accumulated voltage of the series-connected thermoelectric couples. While many thermoelectric modules are made using n-type and p-type semiconductor materials for the thermoelectric elements 104, it will be understood that the invention is not so limited. Many other kinds of materials known and yet to be developed may exhibit the thermoelectric effect, and may be used in embodiments. Similarly, other arrangements of the elements may be envisioned.

Preferably, thermoelectric modules used in embodiments are optimized for power generation. Research has shown that the total power available is maximized when the length “L” of the thermoelectric elements is quite short—for example about 0.5 millimeters. However, the conversion efficiency of a thermoelectric module (the fraction of available thermal energy actually converted to electrical energy) increases with increasing length L. For example, a thermoelectric element with a length of 5.0 millimeters may be several times more efficient than one with a length of 0.5 millimeters. The optimum length for a particular application (providing the minimum cost per expected unit of electrical energy) will be a function of the cost of the thermoelectric modules and associated hardware, the cost of the thermal energy supplied to the thermoelectric generator, and the expected life of the thermoelectric generator. A more complete discussion of the factors involved in optimizing the performance of a thermoelectric module may be found in D. M. Rowe and Gao Min, Evaluation of thermoelectric modules for power generation, Journal of Power Sources 73 (1998) 193-198.

FIG. 2 illustrates a system 200 in accordance with embodiments. A thermoelectric generator (TEG) 201 generates electric power when it is subjected to a temperature differential, for supplying a load 204. In FIG. 2, the temperature differential is provided by a hot fluid 202 and a cold fluid 203 piped to opposite sides of TEG 201. For the purposes of this disclosure, a thermoelectric generator is a device that produces electric power when subjected to a temperature differential. A thermoelectric generator may, but need not, include many thermoelectric modules such as thermoelectric module 100, which may in turn include many thermoelectric elements arranged in thermoelectric couples.

It is to be understood that a temperature differential may be provided by any of many, many different media and apparatus. For example, heated fluid 202 may be produced specifically for the purpose of generating electricity, for example by heating water using conventional fossil fuels, solar energy, or by some other means. Alternatively, heated fluid 202 may be the by-product of an industrial process, waste water from an establishment such as a car wash or laundry, naturally occurring hot spring water, or another kind of fluid.

The “hot” side of a temperature differential may be provided by another medium besides a liquid, for example, air exhausted from a building air conditioning system, exhaust gasses from an engine, the surface of any component such as a vehicle exhaust pipe, oven exterior, blast furnace environment, or other suitable heat source.

Similarly, cold fluid 203 may be obtained specifically for the purpose of power generation, or may be the by-product of some other process. For example, cold fluid 203 may be water that is circulated through an underground pipe to cool the water to the temperature of the ground—typically about 54-57° F. (12-14° C.) in many parts of the United States. Or cold fluid 203 may be any naturally-occurring relatively cold fluid, for example water diverted from a river or stream. The “cold” side of a temperature differential may be provided by media and materials other than fluids, for example ambient air, a metallic object, or some other suitable “cold” source.

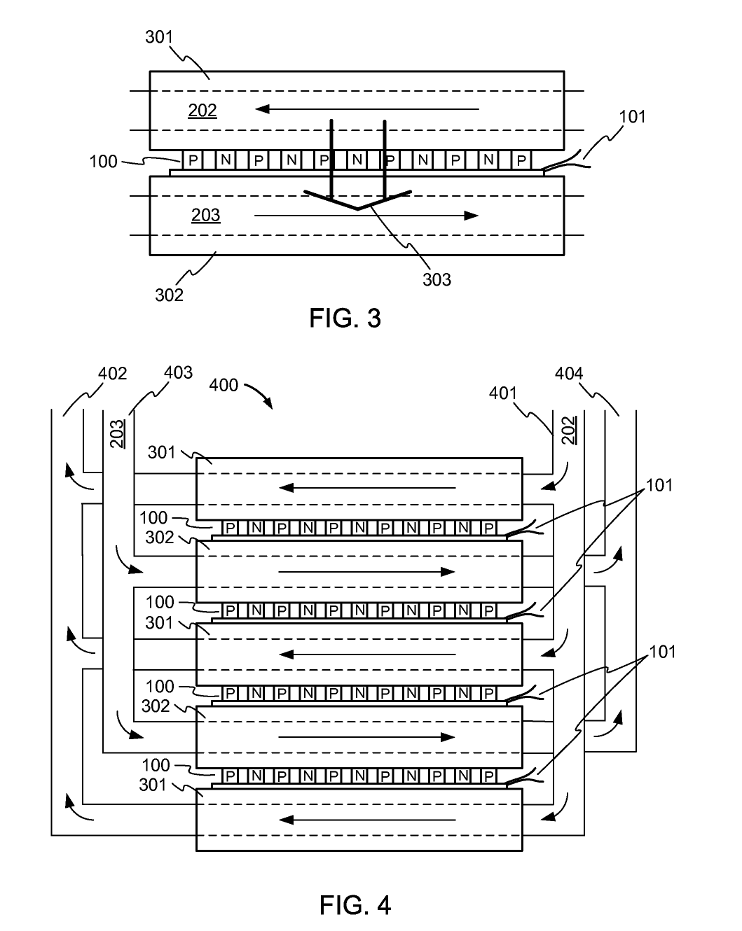

For maximum electric power output, it is advantageous to supply heat to the hot side of each thermoelectric module as efficiently as possible, and to remove heat from the cold side as efficiently as possible. FIG. 3 shows one example arrangement for a single thermoelectric module 100. For the purposes of this disclosure, an element that supplies heat to or receives heat from a thermoelectric module will be referred to as a “thermal element.” In FIG. 3, thermoelectric module 100 is sandwiched between a heat source or hot thermal element 301, and a heat sink or cold thermal element 302. For example, hot thermal element 301 may be a thermally conductive block through which a hot fluid 202 is circulated, and cold thermal element 302 may be a thermally conductive block through which a cold fluid 203 is circulated. Hot thermal element 301 and cold thermal element 302 may be aluminum blocks through which relatively hot and cold water are circulated respectively. It is to be recognized that the terms “hot”, “cold”, “heated”, “cooled”, and the like are used in a relative sense. Hot fluid 202 may not appear hot to normal human senses, and cold fluid 203 may not appear cold. “Hot” and “cold” mean that the hot fluid is at a higher temperature than the cold fluid, and not that a person would necessarily perceive the fluids as “hot” or “cold.” Similarly, a hot thermal element or a cold thermal element or both may be provided by structures other than simple blocks. For example, hot thermal element 301 could be a pipe carrying a hot fluid that is a byproduct of a manufacturing process.

FIG. 3 also illustrates schematically the heat flow 303 from hot fluid 202 through thermoelectric module 100 and to cold fluid 203. To maximize the power generation from thermoelectric module 100, it is desirable to maximize heat flow 303. Heat flow 303 is determined in part by the thermal conductivities of thermal modules 301 and 302, and of the thermoelectric elements in thermoelectric module 100, and by the efficiency of extracting heat from hot fluid 202 and delivering heat to cold fluid 203, which is in turn determined at least in part by the thermal conductivities of the two fluids, and by the effectiveness of convective heat transfer between the fluids and their respective thermal modules

For additional power, it may be desirable to combine the power provided by a number of thermoelectric modules 101. FIG. 4 illustrates one way of constructing a thermoelectric generator 400 having a plurality of thermoelectric modules 100. Each thermoelectric module 100 generates electrical power when subjected to a temperature differential between its two sides. Thermoelectric generator 400 also includes a plurality of hot thermal elements 301 to which heat is supplied by a hot fluid 202, and a plurality of cold thermal elements 302, from which heat is received by a cold fluid 203. The hot and cold thermal elements 301 and 302 are arranged in a stack of alternating hot and cold thermal elements, with a thermoelectric module 100 sandwiched between each adjacent pair of a hot thermal element 301 and cold thermal element 302. While only four thermoelectric modules 100 are shown in FIG. 4, with three hot thermal elements 301 and two cold thermal elements 302, more or fewer thermoelectric modules may be used.

Hot fluid 202 enters thermoelectric generator 400 via hot fluid inlet manifold 401 and exits via hot fluid outlet manifold 402. Cold fluid enters thermoelectric generator 400 via cold fluid inlet manifold 403 and exits via cold fluid outlet manifold 404. The net result is that each of thermoelectric modules 100 is exposed to a temperature differential, by virtue of being between one of hot thermal elements 301 and one of cold thermal elements 302. Thermal energy flowing through each thermoelectric module 100 is converted to electrical energy, and a voltage is developed across each set of electrical leads 101. In some embodiments, leads 101 may be interconnected such that thermoelectric generator 400 produces a single voltage on a single set of leads. For example, thermoelectric modules 100 may be connected in series, so that thermoelectric generator 400 produces a voltage that is the sum of the voltages produced by the individual thermoelectric modules 100.

Many variations are possible, for example the hot and cold thermal elements and fluids may be reversed, more or fewer thermoelectric modules may be used, or banks of thermoelectric modules may be combined in more elaborate way. More detail and descriptions of other arrangements for a thermoelectric generator may be found in co-pending U.S. patent application Ser. No. 10/823,353, filed Apr. 13, 2004 and titled “Same Plane Multiple Thermoelectric Mounting System”, and in co-pending U.S. patent application Ser. No. 12/481,741, filed Jun. 10, 2009 and titled “Thermoelectric Generator”, the entire disclosures of which are hereby incorporated herein. Additional information about thermoelectric generators and their application may be found in co-pending U.S. patent application Ser. No. 12/481,745, filed Jun. 10, 2009 and titled “Integrated Energy System for Whole Home or Building”, and co-pending U.S. patent application Ser. No. 12/481,750, filed Jun. 10, 2009 and titled “Automatic Configuration of Thermoelectric Generator to Load Requirements”, the entire disclosures of which are hereby incorporated herein.

In other embodiments, only one side of a thermoelectric module may receive heat from or supply heat to a fluid flowing in a thermal module. For example, one side of a thermoelectric module may be heated by hot fluid flowing through a thermal element, and the cold side of the thermoelectric module may be cooled by ambient air. In other embodiments, the cold side of a thermoelectric module may be cooled by a cold fluid flowing through a thermal module, and the hot side of the thermoelectric module heated by a static heat source such as the outer surface of an oven or furnace. Many variations are possible.

For maximum power generation, it is desirable to enhance the transfer of heat between the fluid or fluids and their respective thermal elements.

One way of enhancing heat transfer to and from a fluid is to utilize a nanofluid. A nanofluid is a fluid containing particles of a size conveniently expressed in nanometers, typically between 1 and 100 nanometers. The particles are called nanoparticles. The nanoparticles may be colloidal, or may be atomic in size. The addition of nanoparticles to a fluid, for example water, can increase both the thermal conductivity of the fluid and the effectiveness of convective heat transfer between the fluid and surrounding structures. Although the physical mechanism accounting for the increases may not be fully understood, the increases may be affected by the size and concentration of the nanoparticles, the material of the nanoparticles, the temperature at which the fluid characteristics are measured, and other factors.

The inclusion of a nanofluid in a thermoelectric generator can result in a significant improvement in the amount of power generated from a given temperature differential. Alternatively, the inclusion of the nanofluid may enable useful power generation from smaller a temperature differential than would otherwise be considered.

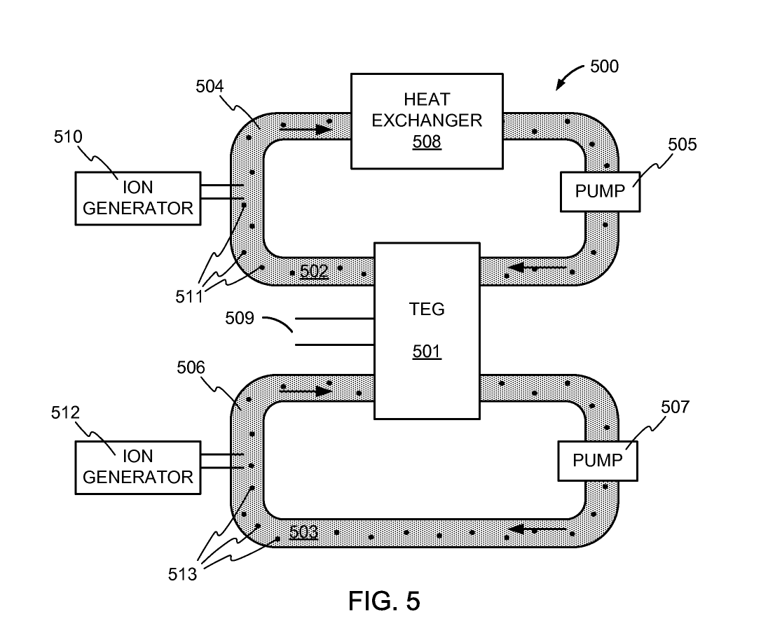

FIG. 5 illustrates a system 500 for utilizing one or more nanofluids in thermoelectric power generation, in accordance with embodiments. In exemplary system 500, a thermoelectric generator 501 generates electrical power from a temperature differential between a hot fluid 502 and a cold fluid 503. In this embodiment, hot fluid 502 circulates in a closed hot fluid loop 504, driven by hot fluid pump 505, and cold fluid 503 circulates in closed cold fluid loop 506, driven by cold fluid pump 507. It is not a requirement that either fluid circulate in a loop, but circulation may be convenient in some embodiments. Heat is supplied to hot fluid 502 through a heat exchanger 508. For example, heat exchanger 508 may be as simple as passing hot fluid loop 504 through a heated area, such as an area where waste heat is exhausted from a building air conditioning system, or through a solar collector for heating. In other embodiments, a more elaborate heat exchanger may be used. Although not shown, cold fluid 503 may be cooled by using a radiator, by passing through an earth coupled piping loop, or by any other suitable means. A heat exchanger may optionally be utilized in cooling cold fluid 503.

Within thermoelectric generator 501, heat from hot fluid 502 is provided to one or more thermoelectric modules, and exhausted to cold fluid 503. The thermoelectric modules generate electricity, which is delivered through leads 509. Internally, thermoelectric generator 501 may include components similar to those discussed above and shown in FIGS. 1-4, or may be of a different construction. For example, thermoelectric generator 501 may be of a construction similar to thermoelectric generator 400 shown in FIG. 4, with hot fluid 502 entering through a hot fluid inlet manifold 401 to be distributed to hot thermal elements 301 and exiting through a hot fluid outlet manifold 402, and cold fluid 503 entering through a cold fluid inlet manifold 403 to be distributed to cold thermal elements 302 and exiting via a cold fluid exit manifold 404.

In some embodiments, thermoelectric generator 501 may be supplied with fluid or fluids already containing nanoparticles. In other embodiments, the nanoparticles may be generated as needed. In exemplary thermoelectric generator 501, a first ion generator 510 generates ions 511 within hot fluid 502, and a second ion generator 512 generates ions 513 within cold fluid 503. The ions are nanoparticles, which are suspended within the respective fluids so that the fluids are nanofluids. In other embodiments, other kinds of nanoparticles may be used other than ions 511 and 513, but the use of ions 511 and 513 as nanoparticles may provide certain benefits as described below. Although both hot and cold fluids 502 and 503 are illustrated as being nanofluids, this is also not a requirement. In some embodiments, only one nanofluid may be present. For example, if the cold side of thermoelectric generator 501 is air cooled, a nanofluid may be used only on the hot side of thermoelectric generator 501.

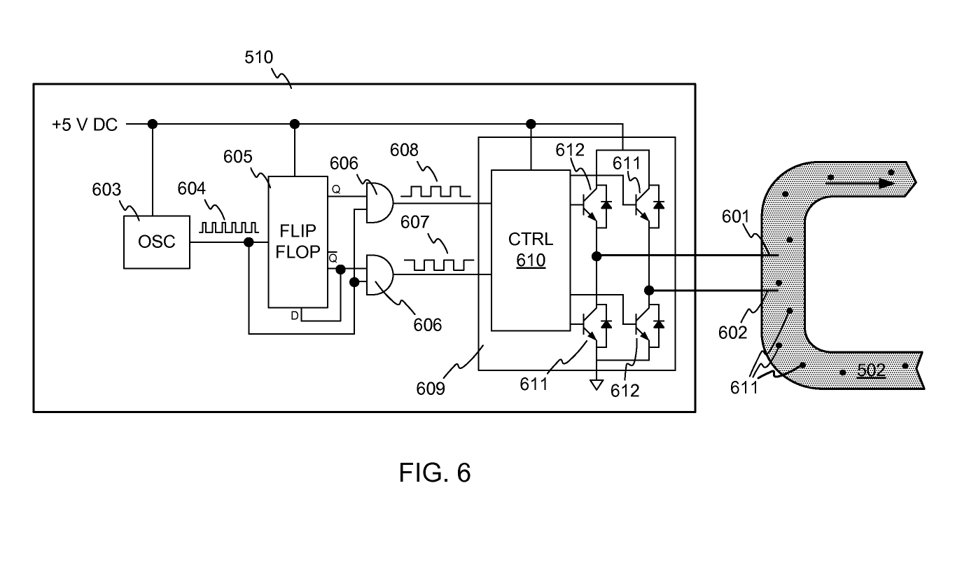

FIG. 6 illustrates the operation of exemplary ion generator 510, in accordance with embodiments. Ion generator 510 includes two electrodes 601 and 602, in contact with flowing hot fluid 502. For example, electrodes 601 and 602 may penetrate the wall of a pipe defining loop 504 to reach flowing fluid 502. In some embodiments, electrodes 601 and 602 are made of sterling silver, which comprises nominally 92.5% silver and 7.5% copper, and thus ion generator 510 produces silver and copper ions in hot fluid 502. Exemplary ion generator 510 impresses a voltage between electrodes 601 and 602, so that ions 511 are generated by electrolysis. As hot fluid 502 circulates, ions 511 are dispersed throughout hot fluid 502. Preferably, the voltage impressed between electrodes 601 and 602 is an alternating voltage. In one example method of producing the alternating voltage, an oscillator 603 produces a train of pulses 604. Oscillator 603 may be, for example, a well-known 555 timer integrated circuit, or another kind of oscillator. Pulse train 604 may be a train of digital pulses, alternating between 0 and 5 nominal volts. Preferably, pulse train 604 is provided to a D flip-flop 605, which has the effect of halving the frequency of pulse train 604 and producing a second pulse train having a 50% duty cycle, regardless of the duty cycle of pulse train 604. The two complementary outputs of D flip-flop 605 are further conditioned by AND gates 606, producing complementary pulse trains 607 and 608, each having a frequency half that of pulse train 604, and a 50% duty cycle.

Complementary pulse trains 607 and 608 may be fed to an H-bridge circuit 609, which may be for example a TA7291SG Bridge Driver available from Toshiba America, Inc., of New York, N.Y. Control circuitry 610 within H-bridge circuit 609 utilizes complementary pulse trains 607 and 608 to switch a set of transistors to alternately impress the voltage on electrodes 601 and 602. For example, when pulse train 607 is at a high level and pulse train 608 is at a low level, transistors 611 may be switched on and transistors 612 may be switched off. Conversely, when pulse train 607 is at a low level and pulse train 608 is at a high level, transistors 611 may be switched off and transistors 612 may be switched on. As a result, electrodes 601 and 602 alternately plate and disperse ions, until an equilibrium concentration of ions 511 is reached in hot fluid 502. Ion generator 510 may be operated whenever thermoelectric generator 501 is in operation, or may be operated intermittently, may be operated only upon startup to build up a concentration of ions 511 in hot fluid 502, or may be operated based on some other scheme.

Many variations in the operation of ion generator 510 are possible, for example in the voltage used, the frequency of operation, and other parameters. In one embodiment, oscillator 603 produces a pulse train 604 having a frequency of about 14 Hz, resulting in a frequency of switching of the voltage between electrodes 601 and 602 of about 7 Hz. Because exemplary ion generator 510 uses digital circuitry, the voltage between electrodes 601 and 602 may switch essentially instantaneously between its extremes. For the purposes of this disclosure, this kind of alternating voltage will be referred to as a “chopped” alternating voltage. A chopped alternating voltage may also be known as a square wave. Using other drive schemes, the alternating voltage may transition smoothly, for example sinusoidally.

Other frequencies may be used, for example 10 Hz, 60 Hz, 120 Hz, 1 kHz, 5 kHz, 10 kHz, 20 kHz, or another suitable frequency. For example, in some embodiments, the alternating voltage between electrodes 601 and 602 may have a frequency of more than 20 kHz. In some embodiments, the alternating voltage between electrodes 601 and 602 maybe about 5 volts, but other voltages may be used, for example 3 volts, 12 volts, 24 volts, or another suitable voltage.

The use of an alternating voltage may have the beneficial effect of preventing the buildup of scale on electrodes 601 and 602, as during operation, each electrode is a donor of material at least some of the time, so that the surface of each electrode is routinely at least partially shed. This cleaning action may serve to maintain good electrical contact between the electrodes and the fluid.

The use of a nanofluid may improve the performance of a thermoelectric generator considerably, as compared with the performance of the same thermoelectric generator without the use of a nanofluid. This improved performance may be exploited to generate additional power from a given temperature differential. Alternatively, the improved performance may be utilized to generate power from a low-grade waste heat source that may not have been previously considered as useful for power generation.

While the generation of ions in accordance with embodiments has been described in the context of thermoelectric power generation, the ion generation techniques described may be used in other applications as well, wherever enhanced heat transfer characteristics of a suitable fluid would be beneficial. Examples may include hydronic heating or cooling systems, solar energy collection, or other applications.

When silver ions are used as nanoparticles, the presence of silver ions may have additional benefits as well. Silver is known to be a safe and effective biocide, and its presence in a fluid of a thermoelectric generator may reduce or prevent the growth of algae and the presence of microorganisms, for example.

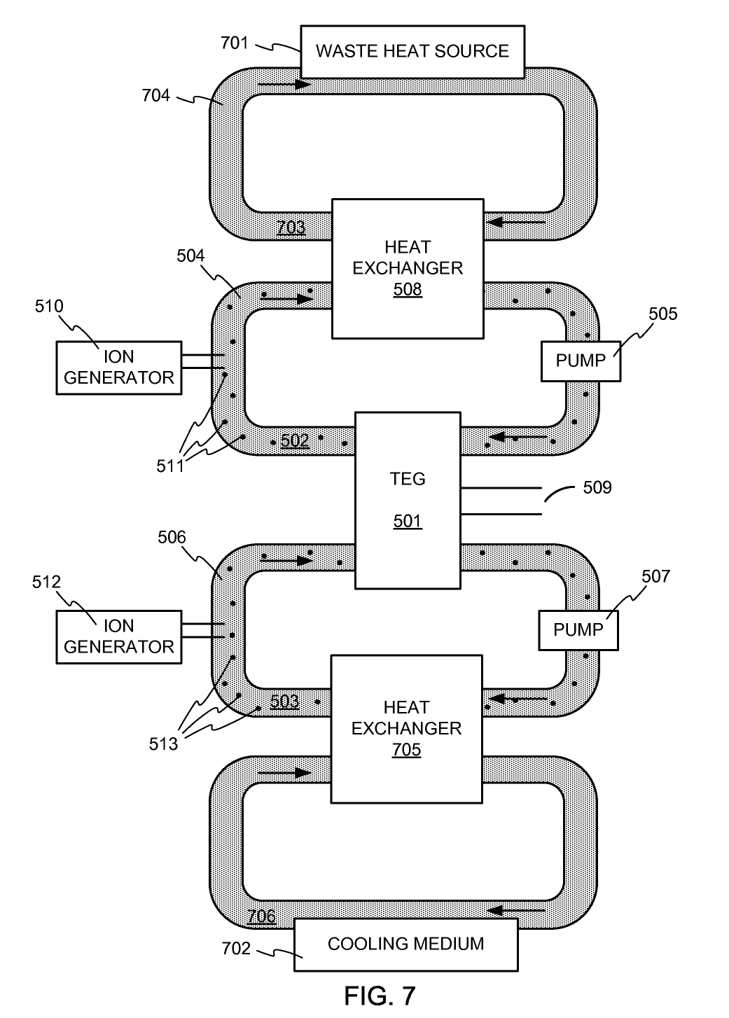

Depending on the nature of the media supplying a temperature differential from which electric power is to be generated, additional components may be desirable. FIG. 7 illustrates a system for generating electricity from a temperature differential between a waste heat source 701 and a cooling medium 702, in accordance with embodiments. In order to minimize the volumes of nanofluids 502 and 503 required and to contain the nanofluids to prevent loss of nanoparticles, additional heat transfer loops may be used to transfer heat to hot fluid 502 and from cold fluid 503 within closed loops 504 and 506. For example, heat from waste heat source 701 may be transferred to a hot side heat transport fluid 703 within a transport loop 704, and then to hot fluid 502 via heat exchanger 508. Hot side heat transport fluid 703 may be circulated by a pump, if necessary. Similarly, heat may be exhausted from cold fluid 503 via heat exchanger 705 to a cold side heat transport fluid 706 and then to cooling medium 702. Hot side and cold side heat transport fluids 703 and 706 may be any suitable fluids, including liquids or gasses, depending on the nature of waste heat source 701 and cooling medium 702. The system may be scaled to utilize any portion or all of the available waste heat and cooling capacity.

Experimental results are given below.

### Experiment 1

In one experimental use, a thermoelectric generator of construction similar to that shown in FIG. 4 was utilized, having 12 thermoelectric modules sandwiched between alternating hot and cold thermal elements. The hot and cold thermal elements were fed from hot and cold fluid inlet manifolds, and the hot and cold fluids were removed via hot and cold fluid outlet manifolds. Both hot and cold fluids were contained within closed loops in a manner similar to that illustrated in FIG. 5. Each closed loop contained about 1.5 liters of water. The closed loops were filled with distilled water, and the system performance was characterized using the distilled water as the working fluid. Ion generators were supplied in both closed loops, and ions were generated such that in some tests both the hot fluid and the cold fluid were nanofluids comprising distilled water and suspended ions. In some tests, only one fluid included suspended ions. To generate the ions, a chopped alternating voltage having a peak-to-peak amplitude of about 5 volts and a frequency of about 7 Hz was supplied to sterling silver electrodes suspended in each closed loop. Each electrode was about 0.128 inches in diameter, and the electrodes were held parallel with a center-to-center distance of about 0.25 inches.

About 1 inch of each electrode was in contact with the water. When nanofluids were used, the performance of the thermoelectric generator was measured after 3 hours of operation, the ion generators having operated continuously during the 3 hour interval before performance measurement.

The presence of the nanofluid improved the performance of the thermoelectric generator by a surprising amount, as compared with the performance of the same thermoelectric generator before the introduction of the ions—that is, without the use of a nanofluid. The results of several test runs are given in the table below.

| | | | | | Volts DC |
|---|---|---|---|---|---|
| | | Temper- | Temper- | Tempera- | produced |
| | | ature | ature | ture Dif- | by TEG at |
| Test | | of Hot | of Cold | ferential, | 3 hours of |
| Number | Fluid Type | Fluid, ° F. | Fluid, ° F. | ° F. | operation |
| 1 | Plain Water | 131 | 54 | 77 | 13.1 |
| 2 | Cold fluid- | 129 | 57 | 72 | 15.9 |
| | plain water | | | | |
| | Hot fluid- | | | | |
| | water with ions | | | | |
| 3 | Both fluids | 132 | 54 | 78 | 18.1 |
| | include ions | | | | |
| 4 | Both fluids | 112 | 50 | 62 | 13.0 |
| | include ions | | | | |
| 5 | Both fluids | 109 | 45 | 64 | 12.2 |
| | include ions | | | | |
| 6 | Both fluids | 149 | 52 | 97 | 21.6 |
| | include ions | | | | |

As can be seen in the table by comparing tests numbers 1 and 2, the addition of ions to only the hot fluid resulted in a substantial increase in voltage produced (15.9 vs. 13.1 Volts), even though test number 2 was conducted using a smaller temperature differential between the two fluids. Comparing tests 1 and 3 reveals that using nanofluids for both the hot and cold fluids resulted in an output voltage increase of about 38% (18.1 vs. 13.1 Volts), even though the temperature differentials used in the two tests were nearly identical. Alternatively, comparing tests 1 and 4 reveals that the addition of ions to the working fluids enabled the production of nearly the same output voltage in test 4 (13.0 Volts) as was produced in test 1 (13.1 Volts), even though the temperature differential utilized in test 4 was considerably smaller than was used in test 1.

### Experiment 2

In another experiment, the system described above, including ion generators in both the hot and cold loops, was allowed to operate for 30 continuous hours. After 30 hours of ion generation, the concentration of silver in one of the closed loops was measured to be about 238 micrograms/liter, and the concentration of copper was measured to be about 362 micrograms/liter. No silver or copper particles were visible via optical or electron microscope, indicating that the nanoparticles were likely non-colloidal atomic silver and copper ions.

The invention has now been described in detail for the purposes of clarity and understanding. However, it will be appreciated that certain changes and modifications may be practiced within the scope of the appended claims.

What is claimed is:

1. A system for generating electricity from a temperature differential, the system comprising:
at least one thermoelectric module having a hot side and a cold side;
a thermal element in contact with one side of the thermoelectric module, to supply heat to or to receive heat from the thermoelectric module;
a fluid flowing through the thermal element, to supply heat to or to receive heat from the thermal element; and
a plurality of nanoparticles suspended in the fluid, wherein the suspended nanoparticles enhance the transfer of heat between the fluid containing the nanoparticles and the thermal element, as compared with a similar fluid not containing the nanoparticles.

2. The system for generating electricity from a temperature differential as recited in claim 1, wherein the thermal element is a hot thermal element in contact with the hot side of the thermoelectric module to supply heat to the thermoelectric module, the fluid is a hot fluid flowing through the hot thermal element to supply heat to the hot thermal element, the nanoparticles are a first plurality of nanoparticles suspended in the hot fluid, and the system further comprises:
a cold thermal element in contact with the cold side of the thermoelectric module, to receive heat from the thermoelectric module;
a cold fluid flowing through the cold thermal element to receive heat from the cold thermal element; and
a second plurality of nanoparticles suspended in the cold fluid, wherein the suspended nanoparticles enhance the transfer of heat between the cold fluid containing the nanoparticles and the thermal element, as compared with a similar fluid not containing the nanoparticles

3. The system for generating electricity from a temperature differential as recited in claim 1, wherein the fluid is water, and wherein the suspended nanoparticles comprise copper ions, silver ions, or both copper and silver ions.

4. The system for generating electricity from a temperature differential as recited in claim 3, wherein the ions are less than 2 nanometers in diameter.

5. The system for generating electricity from a temperature differential as recited in claim 3, wherein the ions are non-colloidal.

6. The system for generating electricity from a temperature differential as recited in claim 3, wherein the fluid contains copper ions in a concentration of between 250 and 450 micrograms per liter.

7. The system for generating electricity from a temperature differential as recited in claim 3, wherein the fluid contains silver ions in a concentration of between 150 and 350 micrograms per liter

8. The system for generating electricity from a temperature differential as recited in claim 1, wherein the fluid is contained within a closed loop.

9. The system for generating electricity from a temperature differential as recited in claim 8, further comprising a heat exchanger that transfers heat from an external source to the fluid to heat the fluid, or transfers heat from the fluid to an external sink to cool the fluid.

10. The system for generating electricity from a temperature differential as recited in claim 1, further comprising an ion generator that generates the nanoparticles.

11. The system for generating electricity from a temperature differential as recited in claim 10, wherein the ion generator comprises:
a spaced apart pair of electrodes in contact with the fluid; and
a drive circuit that applies an alternating voltage between the electrodes.

12. The system for generating electricity from a temperature differential as recited in claim 11, wherein the alternating voltage is a chopped alternating voltage.

13. The system for generating electricity from a temperature differential as recited in claim 11, wherein each electrode is made of sterling silver.

14. The system for generating electricity from a temperature differential as recited in claim 11, wherein the alternating voltage has a peak-to-peak amplitude of between 4 and 6 volts.

15. The system for generating electricity from a temperature differential as recited in claim 11, wherein the alternating voltage has a frequency of between 6 and 8 Hz.

16. The system for generating electricity from a temperature differential as recited in claim 11, wherein the alternating voltage has a frequency greater than 20 kHz.

17. The system for generating electricity from a temperature differential as recited in claim 1, wherein the system comprises:
a plurality of thermoelectric modules having hot and cold sides; and
a plurality of thermal elements in contact the thermoelectric modules, to supply heat to or to receive heat from the thermoelectric module;
wherein the fluid flows through the plurality of thermal elements, to supply heat to or to receive heat from at least some of the thermal elements.

18. An ion generator for generating ions in a fluid, the ion generator comprising:
a spaced apart pair of electrodes in contact with the fluid; and
a drive circuit that applies an alternating voltage between the electrodes, the alternating voltage having a frequency of at least 6 Hz.

19. The ion generator for generating ions in a fluid as recited in claim 18, wherein the alternating voltage is a chopped alternating voltage.

20. The ion generator for generating ions in a fluid as recited in claim 18, wherein each electrode comprises copper, silver, or both.

21. The ion generator for generating ions in a fluid as recited in claim 20, wherein both electrodes are made of sterling silver.

22. The ion generator for generating ions in a fluid as recited in claim 20, wherein the alternating voltage alternates at a frequency between 6 Hz and 8 Hz.

23. The ion generator for generating ions in a fluid as recited in claim 20, wherein the alternating voltage alternates at a frequency greater than 20 kHz.

24. A method of generating electricity from a temperature differential, the method comprising:
placing a thermal element in contact with a side of a thermoelectric module;
passing a fluid through the thermal element to supply heat to or to receive heat from the thermoelectric module; and
suspending nanoparticles within the fluid, the nanoparticles enhancing the transfer of heat between the fluid containing the nanoparticles and the thermal element as compared with a similar fluid not containing the nanoparticles.

25. The method of generating electricity from a temperature differential as recited in claim 24, wherein the thermal element is a hot thermal element in contact with a hot side of the thermoelectric module and the fluid is a hot fluid that supplies heat to the thermoelectric module, and wherein the method further comprises:
placing a cold thermal element in contact with a cold side of the thermoelectric module;
passing a cold fluid through the cold thermal element to receive heat from the thermoelectric module; and
suspending nanoparticles within the cold fluid, the nanoparticles enhancing the transfer of heat between the cold fluid containing the nanoparticles and the cold thermal element as compared with a similar fluid not containing the nanoparticles.

26. The method of generating electricity from a temperature differential as recited in claim 24, wherein suspending nanoparticles within the fluid comprises:
providing a pair of spaced apart electrodes in contact with the fluid; and
impressing an alternating voltage between the electrodes to generate nanoparticles via electrolysis.

27. The method of generating electricity from a temperature differential as recited in claim 26, wherein providing a pair of spaced apart electrodes in contact with the fluid comprises providing at least one electrode that comprises silver, copper, or both silver and copper.

28. The method of generating electricity from a temperature differential as recited in claim 26, wherein providing a pair of spaced apart electrodes in contact with the fluid comprises providing a pair of sterling silver electrodes.

29. The method of generating electricity from a temperature differential as recited in claim 26, wherein impressing the alternating voltage between the electrodes comprises impressing a chopped alternating voltage between the electrodes.

30. The method of generating electricity from a temperature differential as recited in claim 26, further comprising impressing the alternating voltage between the electrodes continuously during the generation of electricity by the thermoelectric module.

31. The method of generating electricity from a temperature differential as recited in claim 26, wherein impressing the alternating voltage between the electrodes comprises impressing an alternating voltage having a frequency between 6 and 8 Hz between the electrodes.
